(19) United States
(12) Patent Application Publication
(10) Pub. No.: US 2011/0297950 A1
(43) Pub. Date: Dec. 8, 2011

(54) CRYSTALLINE SEMICONDUCTOR FILM MANUFACTURING METHOD, SUBSTRATE COATED WITH CRYSTALLINE SEMICONDUCTOR FILM, AND THIN-FILM TRANSISTOR

(75) Inventors: Tomoya KATO, Chiba (JP); Tomohiko ODA, Osaka (JP); Sei OOTAKA, Kyoto (JP)

(73) Assignees: PANASONIC LIQUID CRYSTAL DISPLAY CO., LTD., Hyogo (JP); PANASONIC CORPORATION, Osaka (JP)

(21) Appl. No.: 13/212,465

(22) Filed: Aug. 18, 2011

Related U.S. Application Data
(63) Continuation of application No. PCT/JP2010/003157, filed on May 10, 2010.

(51) Int. Cl. H01L 29/786; H01L 21/336

(52) U.S. Cl. 257/66; 438/487; 257/E29.273; 257/E21.414

(57) ABSTRACT

To provide a method of manufacturing a crystalline semiconductor film having a crystal structure with favorable in-plane uniformity. The method includes: irradiating an amorphous semiconductor film with a continuous-wave laser beam to increase a temperature of the amorphous semiconductor film to a range of 600° C. to 1100° C., the continuous-wave laser beam having a light intensity distribution continuously convex upward on each of major and minor axes; crystallizing the amorphous semiconductor film at the temperature increased to the range of 600° C. to 1100° C.; and increasing a crystal grain size of the crystallized amorphous semiconductor film, as a result of an increase in an in-plane temperature of the crystallized amorphous film to a range of 1100° C. to 1414° C. by latent heat released in the crystallizing of the amorphous semiconductor film.

### CROSS REFERENCE TO RELATED APPLICATION

This is a continuation application of PCT application No. PCT/JP2010/003157 filed on May 10, 2010, designating the United States of America.

### BACKGROUND OF THE INVENTION

(1) Field of the Invention

The present invention relates to a method of manufacturing a crystalline semiconductor film, a method of manufacturing a substrate coated with a crystalline semiconductor film, and a thin-film transistor.

(2) Description of the Related Art

Examples used for manufacturing a liquid crystal panel or an organic electroluminescence (EL) panel designed for a display device include a thin-film transistor (TFT). A semiconductor layer which is made of, for example, silicon and serves as a channel part of the thin-film transistor is formed, in general, from an amorphous semiconductor film or a crystalline semiconductor film. It is preferable that a semiconductor film serving as the channel part of the thin-film transistor be formed from a crystalline semiconductor film, which has a higher mobility as compared with amorphous silicon. Generally speaking, an amorphous semiconductor film is firstly formed, and then a crystalline semiconductor film is formed as a result of crystallizing the amorphous semiconductor film.

Examples of the methods of manufacturing a crystalline semiconductor film from an amorphous semiconductor film include: excimer laser annealing (ELA); thermal annealing crystallization using a nickel (Ni) catalyst or the like; and crystallization using a combination of an infrared semiconductor laser light and a sample structure having a light-absorbing layer.

In the case of crystallization according to the ELA method, since a crystalline semiconductor film is formed from microcrystals or polycrystals, electrical characteristics of the crystalline semiconductor film vary according to the size and distribution of crystal grains (crystal structure). For this reason, when crystalline semiconductor films are used for manufacturing thin-film transistors, the characteristic variation occurs among the thin-film transistors.

In the case of thermal annealing crystallization, although uniform crystallization can be achieved, it is difficult to process catalyst metals. In the case of crystallization using the combination of an infrared semiconductor laser light and a sample structure having a light-absorbing layer, a process is required to form a film from a light-absorbing layer and a buffer layer as samples and then perform removal, which leads to a problem in terms of tact. Moreover, a thin-film transistor manufactured using a film crystallized using one of these solid phase growth techniques has a problem of not achieving target electrical characteristics due to a small average grain size of the film.

To address this problem, Japanese Unexamined Patent Application Publication No. 2008-85317 (referred to as Patent Reference 1 hereafter) discloses a technique capable of controlling a crystal grain size of a crystalline semiconductor film included in a thin-film transistor. Moreover, Japanese Unexamined Patent Application Publication No. 2008-85318 (referred to as Patent Reference 2 hereafter) discloses a technique capable of controlling a grain boundary direction and a crystal grain size of a crystalline semiconductor film included in a thin-film transistor.

The techniques disclosed by Patent References 1 and 2 can form a crystalline semiconductor film having a large grain size of 0.5 μm to 10 μm by growing crystals in a predetermined direction using a laser beam. Moreover, using a semiconductor element made from such a film, an excellent semiconductor device can be manufactured which has less variation between adjacent crystals.

### SUMMARY OF THE INVENTION

However, each of Patent References 1 and 2 only discloses the technique to form a crystalline semiconductor film having large crystal grains.

The ELA method crystallizes an amorphous semiconductor film using a pulsed laser beam, such as a xenon chlorine (XeCl) excimer laser beam whose wavelength λ is 308 nm. To be more specific, the temperature of the amorphous semiconductor film is increased instantaneously by the pulsed excimer laser beam (an irradiation time is on the order of nanoseconds). As a result, the amorphous semiconductor film is melted and then crystallized. Here, as mentioned, the pulsed excimer laser beam is applied for a period of time as short as nanoseconds. Although the amorphous semiconductor film is crystallized only after being melted at the melting point of a semiconductor film (silicon) (i.e., 1414° C.) or higher, the crystal grain size varies depending on a condition. Moreover, a volume expansion in a crystallization process of the amorphous semiconductor film, that is, the volume expansion from liquid (in the melted state) to solid (in the crystallized state) causes protrusions on the surface of the crystallized crystalline semiconductor film, resulting in a loss of flatness. In other words, in-plane variation is caused in the grain size of the crystalline semiconductor film. This variation becomes a problem in a process, such as an etching process, to manufacture a thin-film transistor. Also, a multiple number of beam shots are required to counter the in-plane variation of the crystallized crystalline semiconductor film, and this leads to a problem in terms of cost and tact.

Moreover, when a voltage is applied to, for example, a gate electrode of a thin-film transistor having such a crystalline semiconductor film, the amount of current flowing between a source and a drain varies. Suppose, for example, that a current-driven display device, such as an organic EL display device, includes the above thin-film transistor. In this case, since the gradation of the organic EL is controlled by the current, the variation in the amount of current directly leads to the variation in displayed images. Thus, a high-precision image cannot be obtained. Also, the protrusions on the surface of the crystalline semiconductor film result in leakage current between the source and the drain, thereby deteriorating the characteristics of the thin-film transistor.

Although Patent References 1 and 2 disclose the techniques to control the grain size in order to address the aforementioned problem of the ELA method, the problem caused by the surface protrusions is not solved and is not even mentioned by Patent References 1 and 2.

The present invention is conceived in view of the stated problem, and has an object to provide a method of manufacturing a crystalline semiconductor film having a crystal structure with favorable in-plane uniformity, a method of manufacturing a substrate coated with a crystalline semiconductor film, and a thin-film transistor.

In order to achieve the aforementioned object, the method of manufacturing the crystalline semiconductor film according to an aspect of the present invention includes: irradiating an amorphous semiconductor film with a continuous-wave laser beam to increase a temperature of the amorphous semiconductor film to a range of 600° C. to 1100° C., the continuous-wave laser beam having a light intensity distribution which is continuously convex upward on each of major and minor axes; crystallizing the amorphous semiconductor film irradiated with the continuous-wave laser beam in the irradiating, at the temperature increased to the range of 600° C. to 1100° C.; and increasing a crystal grain size of the crystallized amorphous semiconductor film, as a result of an increase in an in-plane temperature of the crystallized amorphous film to a range of 1100° C. to 1414° C. by latent heat released in the crystallizing of the amorphous semiconductor film irradiated with the continuous-wave laser beam, wherein the light intensity distribution continuously convex upward has a width where a light intensity is equal to or higher than a predetermined intensity in a major axis direction, and the width corresponds to a width of an area included in the amorphous semiconductor film and increased in temperature to the range of 1100° C. to 1414° C. by the latent heat.

The present invention can implement a method of manufacturing a crystalline semiconductor film having a crystal structure with favorable in-plane uniformity, a method of manufacturing a substrate coated with a crystalline semiconductor film, and a thin-film transistor.

### FURTHER INFORMATION ABOUT TECHNICAL BACKGROUND TO THIS APPLICATION

The disclosure of PCT application No. PCT/JP2010/003157 filed on May 10, 2010, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a diagram showing an example of a configuration of a continuous-wave (CW) laser crystallization device in a first embodiment;

FIG. 2A is a diagram showing a minor-axis profile of a CW laser beam in the first embodiment;

FIG. 2B is a diagram showing a major-axis profile of the CW laser beam in the first embodiment;

FIG. 3A is a diagram showing a minor-axis profile of a CW laser beam;

FIG. 3B is a diagram showing a major-axis profile of the CW laser beam;

FIG. 4 is a diagram explaining a problem in crystallization performed using a longitudinal flat-top beam;

FIG. 5A is a diagram showing an example of a crystal structure resulting from solid phase crystallization (SPC);

FIG. 5B is a diagram showing an example of a crystal structure resulting from crystallization performed using the CW laser beam in the first embodiment;

FIG. 5C is a diagram showing, for comparison, an example of a crystal structure of polycrystalline silicon formed by furnace annealing or the like;

FIG. 6 is a diagram showing a relationship between temperature and energy in silicon crystallization;

FIG. 7 is a diagram explaining a growth mechanism of a crystal structure resulting from explosive nucleation (Ex);

FIG. 8 is a diagram explaining crystallization performed using the CW laser beam in the first embodiment;

FIG. 9 is a diagram explaining an example of the application of the crystalline semiconductor film to a substrate, in a second embodiment;

FIG. 10 is a diagram explaining a method of manufacturing a bottom-gate thin-film transistor in the second embodiment;

FIG. 11 is a flowchart explaining the method of manufacturing the bottom-gate thin-film transistor in the second embodiment;

FIG. 12 is a diagram showing a configuration of the bottom-gate thin-film transistor including the crystalline semiconductor film, in the second embodiment;

FIG. 13 is a diagram explaining the case where a plurality of bottom-gate thin-film transistors are manufactured at one time;

FIG. 14 is a diagram explaining a method of manufacturing a top-gate thin-film transistor in a third embodiment;

FIG. 15 is a diagram showing a configuration of a top-gate thin-film transistor in the third embodiment;

FIG. 16 is a diagram showing another configuration of a top-gate thin-film transistor in the third embodiment; and

FIG. 17 is a flowchart explaining the method of manufacturing the top-gate thin-film transistor in the third embodiment.

### DESCRIPTION OF THE PREFERRED EMBODIMENTS

The method of manufacturing the crystalline semiconductor film according to an aspect of the present invention includes: irradiating an amorphous semiconductor film with a continuous-wave laser beam to increase a temperature of the amorphous semiconductor film to a range of 600° C. to 1100° C., the continuous-wave laser beam having a light intensity distribution which is continuously convex upward on each of major and minor axes; crystallizing the amorphous semiconductor film irradiated with the continuous-wave laser beam in the irradiating, at the temperature increased to the range of 600° C. to 1100° C.; and increasing a crystal grain size of the crystallized amorphous semiconductor film, as a result of an increase in an in-plane temperature of the crystallized amorphous film to a range of 1100° C. to 1414° C. by latent heat released in the crystallizing of the amorphous semiconductor film irradiated with the continuous-wave laser beam, wherein the light intensity distribution continuously convex upward has a width where a light intensity is equal to or higher than a predetermined intensity in a major axis direction, and the width corresponds to a width of an area included in the amorphous semiconductor film and increased in temperature to the range of 1100° C. to 1414° C. by the latent heat.

For example, a continuous-wave (CW) laser beam, such as a green laser light or a blue laser light, is emitted for a relatively long period of time of 10 microseconds to 100 microseconds, instead of a short period of time of 10 nanoseconds to 100 nanoseconds. According to the present aspect, the amorphous semiconductor film is irradiated at a power density such that the temperature of the amorphous semiconductor film is in a range of 600° C. to 1100° C. With the irradiation that instantaneously increases the temperature of the amorphous semiconductor film into the range of 600° C. to 1100° C., the temperature of the amorphous semiconductor film is further increased by latent heat of crystallization. Thus, the amorphous semiconductor film reaches a temperature: which is higher than a temperature considered to be the melting point of amorphous silicon that varies depending on an atomic network structure of amorphous silicon; and which is equal to or lower than the melting point of crystalline silicon, i.e., 1414° C. As a result, the crystal grain size is slightly increased as compared with the size of a crystal obtained by the solid phase growth mechanism, and the uniformity is maintained as well. Moreover, no surface protrusions are caused. Accordingly, the amorphous semiconductor film is formed into a crystalline semiconductor film which is of high quality in manufacturing, for example, a thin-film transistor. With this, the characteristics of a thin-film transistor device including the aforementioned semiconductor film can be enhanced, by preventing surface protrusions and maintaining the surface flatness of the semiconductor film.

In this way, the method of manufacturing the crystalline semiconductor film having a crystal structure with favorable in-plane uniformity can be implemented.

Here, the light intensity distribution which is continuously convex upward is a Gaussian distribution.

In the irradiating, the amorphous semiconductor film is irradiated with the continuous-wave laser beam so that the temperature of the amorphous semiconductor film is in a range of 600° C. to 800° C.

According to the present aspect, when the temperature range of the amorphous semiconductor film is from 600° C. to 800° C. in the irradiating, the same advantageous effect can be achieved as in the case where the temperature range is from 600° C. to 1100° C.

Moreover, in the irradiating, the amorphous semiconductor film is irradiated with the continuous-wave laser beam for a period of time on the order of microseconds.

According to the present aspect, the amorphous semiconductor film can be irradiated with the CW laser beam for a longer time. This can secure sufficient time for the atomic structure of the amorphous semiconductor film to crystallize from the amorphous state and for the atoms to rearrange themselves from the amorphous state.

Moreover, in the irradiating, the amorphous semiconductor film is irradiated with the continuous-wave laser beam for 10 microseconds to 100 microseconds.

According to this aspect, the amorphous semiconductor film can be irradiated with the CW laser beam for a longer time. This can secure sufficient time for the atoms on the amorphous semiconductor film to rearrange themselves to crystallize from the amorphous state.

Furthermore, the method includes, prior to the irradiating: preparing a base material; arranging a plurality of gate electrodes at predetermined intervals above the base material; forming an insulating film over the gate electrodes arranged at the predetermined intervals; and forming the amorphous semiconductor film on the insulating film, wherein a certain width of the light intensity distribution is defined in the major axis direction to increase, to the range of 1100° C. to 1414° C. by the latent heat, a temperature of the area which is included in the amorphous semiconductor film and positionally corresponds to the gate electrodes arranged at the predetermined intervals.

In the present aspect, the width of the Gaussian distribution of the CW laser beam in the major axis direction corresponds to the width of the area which is included in the amorphous semiconductor film and positionally corresponds to the gate electrodes arranged at the predetermined intervals. Thus, the area which positionally corresponds to the gate electrodes can be selectively irradiated, meaning that an area included in the crystalline semiconductor film to be formed as a channel part of the thin-film transistor can be selectively micro-crystallized. As a result, a flat-surface crystalline semiconductor film can be formed as the channel part.

Moreover, the width of the area which is included in the amorphous semiconductor film and positionally corresponds to the gate electrodes arranged at the predetermined intervals may be wider than a width of each of the gate electrodes.

The substrate coated with a crystalline semiconductor film in another aspect according to the present invention includes: a base material; a plurality of gate electrodes arranged above the base material; an insulating film formed over the gate electrodes; and a crystalline semiconductor film formed to cover the insulating film formed over the gate electrodes arranged above the base material, wherein the crystalline semiconductor film includes: a first area formed from crystal grains with an average size of 40 nm to 60 nm and seamlessly formed over an area where the gate electrodes are arranged; and a second area formed from crystal grains with an average size of 25 nm to 35 nm and located adjacent to the first area.

According to the present aspect, the first area included in the crystalline semiconductor film and formed from the crystal grains whose average size is 40 nm to 60 nm is seamlessly formed on the area where the gate electrodes are arranged. The thin-film transistor manufactured using such a crystalline semiconductor film can secure the mobility to obtain adequate ON characteristics as the thin-film transistor to be used in an organic EL display device.

Moreover, the crystalline semiconductor film may include a mixed amorphous-crystalline crystal.

For example, the crystalline semiconductor film includes a mixed amorphous-crystalline crystal. That is, the mixed crystal includes a crystal grain with the average size of 40 nm to 60 nm and an amorphous area around the crystal gain. This structure can reduce the surface roughness.

Furthermore, the gate electrodes may be arranged in a row, above the base material, and the first area included in the crystalline semiconductor film and formed from the crystal grains with the average size of 40 nm to 60 nm may be in a seamless belt-like shape and formed over the area where the gate electrodes are arranged in the row.

According to the present aspect, the first area included in the crystalline semiconductor film and formed from the crystal grains whose average size is 40 nm to 60 nm is seamlessly formed on the area where the gate electrodes are arranged. The substrate coated with the crystalline semiconductor film in the present aspect can be divided into multiple pieces along the aforementioned belt-like area according to the dicing method or the like. Thus, the present aspect can implement the substrate coated with the semiconductor film which can be easily divided into multiple pieces according to the dicing method or the like.

Moreover, the first area included in the crystalline semiconductor film and formed from the crystal grains with the average size of 40 nm to 60 nm may be formed by: irradiating an amorphous semiconductor film with a continuous-wave laser beam to increase a temperature of the amorphous semiconductor film to a range of 600° C. to 800° C., the continuous-wave laser beam having a light intensity distribution which is continuously convex upward on each of major and minor axes; crystallizing the amorphous semiconductor film irradiated with the continuous-wave laser beam in the irradiating, at the temperature increased to the range of 600° C. to 800° C.; and increasing a crystal grain size of the crystallized amorphous semiconductor film, as a result of an increase in an in-plane temperature of the crystallized amorphous film to a range of 1100° C. to 1414° C. by latent heat released in the crystallizing of the amorphous semiconductor film irradiated with the continuous-wave laser beam, wherein the light intensity distribution continuously convex upward is defined on the major axis to ensure a certain width of an area included in the amorphous semiconductor film and increased in temperature to the range of 1100° C. to 1414° C. by the latent heat, and the area included in the amorphous semiconductor film and increased in temperature to the range of 1100° C. to 1414° C. by the latent heat corresponds to the first area.

For example, in the irradiating according to the present aspect, the CW laser beam, such as a green laser light or a blue laser light, is emitted to the amorphous semiconductor film for a period of time on the order of microseconds, instead of the order of nanoseconds, to increase the temperature of the amorphous semiconductor film into the range of 600° C. to 800° C. In the irradiating, when the entire surface of the amorphous semiconductor film is irradiated so that the temperature of the amorphous semiconductor film is in the range of 600° C. to 800° C., crystallization is also achieved at 1414° C. or lower by the latent heat caused to the amorphous semiconductor film. As a result, the size of crystal grains is relatively small and no surface protrusions are formed, thereby leading to no problem.

In the crystallizing, the amorphous semiconductor film is irradiated so that the temperature of the amorphous semiconductor film is in the range of 600° C. to 800° C., instead of the range of 1100° C. to 1414° C. With this irradiation, the temperature of the amorphous semiconductor film is increased to the range of 1100° C. to 1414° C. by the latent heat caused to the amorphous semiconductor film.

In the increasing following the crystallizing, since the amorphous semiconductor film is melted to crystallize at a temperature of 1414° C. or lower, the average size of crystal grains is 40 nm to 60 nm which is relatively small. Also, no protrusions are caused on the surface of the crystalline semiconductor film formed by the crystallization as described and, therefore, the surface flatness of the crystalline semiconductor film can be maintained. This can enhance the characteristics of the thin-film transistor including this crystalline semiconductor film.

It should be noted that, when the irradiation is performed so that the temperature of the entire surface of the amorphous semiconductor film is in the range of 1100° C. to 1414° C., the latent heat caused to the amorphous semiconductor film may develop an area whose temperature is higher than 1414° C. in the amorphous semiconductor film. The amorphous semiconductor film crystallized while including the area with the temperature higher than 1414° C. may end up having a surface protrusion of, for example, 50 nm which is identical in length to the thickness of the amorphous semiconductor film.

As described, according to the present aspect, the amorphous semiconductor film is irradiated with the laser beam so that the temperature of the amorphous semiconductor film is in the range of 600° C. to 800° C. With this irradiation, the temperature of the amorphous semiconductor film is increased to the range of 1100° C. to 1414° C. by the latent heat, and the amorphous semiconductor film is accordingly crystallized. Thus, the amorphous semiconductor film has no area crystallized at a temperature higher than 1414° C. As a result, the crystalline semiconductor film having no surface protrusions and maintaining the surface flatness can be formed. Also, the substrate coated with this crystalline semiconductor film can be implemented.

The thin-film transistor in an aspect according to the present invention is a bottom-gate thin-film transistor including: a gate electrode; an insulating film formed on the gate electrode; a crystalline semiconductor film formed on the insulating film; and a source-drain electrode formed on the crystalline semiconductor film, wherein the crystalline semiconductor film is formed from crystal grains with an average size of 40 nm to 60 nm, and each of the crystal grains are formed by: irradiating an amorphous semiconductor film with a continuous-wave laser beam to increase a temperature of the amorphous semiconductor film to a range of 600° C. to 800° C., the continuous-wave laser beam having a light intensity distribution which is continuously convex upward on each of major and minor axes; crystallizing the amorphous semiconductor film irradiated with the continuous-wave laser beam in the irradiating, at the temperature increased to the range of 600° C. to 800° C.; and increasing a crystal grain size of the crystallized amorphous semiconductor film, as a result of an increase in an in-plane temperature of the crystallized amorphous film to a range of 1100° C. to 1414° C. by latent heat released in the crystallizing of the amorphous semiconductor film irradiated with the continuous-wave laser beam, wherein the light intensity distribution continuously convex upward is defined on the major axis to ensure a certain width of an area included in the amorphous semiconductor film and increased in temperature to the range of 1100° C. to 1414° C. by the latent heat.

According to the present aspect, the amorphous semiconductor film is irradiated with the laser beam so that the temperature of the amorphous semiconductor film is in the range of 600° C. to 800° C. With this irradiation, the temperature of the amorphous semiconductor film is increased to the range of 1100° C. to 1414° C. by the latent heat, and the amorphous semiconductor film is accordingly crystallized. Thus, the amorphous semiconductor film has no area crystallized at a temperature higher than 1414° C. As a result, the crystalline semiconductor film having no surface protrusions and maintaining the surface flatness can be formed. Also, the thin-film transistor having this crystalline semiconductor film can be implemented.

The substrate coated with a crystalline semiconductor film in an aspect according to the present invention includes: a base material; a plurality of source-drain electrodes arranged above the base material; an insulating film formed over the source-drain electrodes; and a crystalline semiconductor film formed to cover the insulating film formed over the source-drain electrodes arranged above the base material, wherein the crystalline semiconductor film includes: a first area formed from crystal grains with an average size of 40 nm to 60 nm and seamlessly formed over an area where the source-drain electrodes are arranged; and a second area formed from crystal grains with an average size of 25 nm to 35 nm and located adjacent to the first area.

According to the present aspect, the first area included in the crystalline semiconductor film and formed from the crystal grains whose average size is 40 nm to 60 nm is seamlessly formed on the area where the gate electrodes are arranged. The thin-film transistor manufactured using such a crystalline semiconductor film can secure the mobility to obtain adequate ON characteristics as the thin-film transistor to be used in an organic EL display device.

Moreover, the crystalline semiconductor film may include a mixed amorphous-crystalline crystal.

According to the present aspect, the crystalline semiconductor film includes a mixed amorphous-crystalline crystal. That is, the mixed crystal includes a crystal grain with the average size of 40 nm to 60 nm and an amorphous area around the crystal gain. This structure can reduce the surface roughness.

Moreover, the gate electrodes may be arranged in a row, above the base material, and the first area included in the crystalline semiconductor film and formed from the crystal grains with the average size of 40 nm to 60 nm may be in a seamless belt-like shape and formed over the area where the gate electrodes are arranged in the row.

According to the present aspect, the first area included in the crystalline semiconductor film and formed from the crystal grains whose average size is 40 nm to 60 nm is seamlessly formed on the area where the gate electrodes are arranged. The substrate coated with the crystalline semiconductor film in the present aspect can be divided into multiple pieces along the aforementioned belt-like area according to the dicing method or the like. Thus, the present aspect can implement the substrate coated with the semiconductor film which can be easily divided into multiple pieces according to the dicing method or the like.

Furthermore, the first area included in the crystalline semiconductor film and formed from the crystal grains with the average size of 40 nm to 60 nm is formed by: irradiating an amorphous semiconductor film with a continuous-wave laser beam to increase a temperature of the amorphous semiconductor film to a range of 600° C. to 800° C., the continuous-wave laser beam having a light intensity distribution which is continuously convex upward on each of major and minor axes; crystallizing the amorphous semiconductor film irradiated with the continuous-wave laser beam in the irradiating, at the temperature increased to the range of 600° C. to 800° C.; and increasing a crystal grain size of the crystallized amorphous semiconductor film, as a result of an increase in an in-plane temperature of the crystallized amorphous film to a range of 1100° C. to 1414° C. by latent heat released in the crystallizing of the amorphous semiconductor film irradiated with the continuous-wave laser beam, wherein the light intensity distribution continuously convex upward is defined on the major axis to ensure a certain width of an area included in the amorphous semiconductor film and increased in temperature to the range of 1100° C. to 1414° C. by the latent heat, and the area included in the amorphous semiconductor film and increased in temperature to the range of 1100° C. to 1414° C. by the latent heat corresponds to the first area.

According to the present aspect, the amorphous semiconductor film is irradiated with the laser beam so that the temperature of the amorphous semiconductor film is in the range of 600° C. to 800° C. With this irradiation, the temperature of the amorphous semiconductor film is increased to the range of 1100° C. to 1414° C. by the latent heat, and the amorphous semiconductor film is accordingly crystallized. Thus, the amorphous semiconductor film has no area crystallized at a temperature higher than 1414° C. As a result, the crystalline semiconductor film having no surface protrusions and maintaining the surface flatness can be formed. Also, the substrate coated with this crystalline semiconductor film can be implemented.

The thin-film transistor in an aspect according to the present invention is a top-gate thin-film transistor including: a source-drain electrode; a crystalline semiconductor film formed on the source-drain electrode; an insulating film formed on the crystalline semiconductor film; and a gate electrode formed on the insulating film, wherein the crystalline semiconductor film is formed from crystal grains with an average size of 40 nm to 60 nm, and each of the crystal grains are formed by: irradiating an amorphous semiconductor film with a continuous-wave laser beam to increase a temperature of the amorphous semiconductor film to a range of 600° C. to 800° C., the continuous-wave laser beam having a light intensity distribution which is continuously convex upward on each of major and minor axes; crystallizing the amorphous semiconductor film irradiated with the continuous-wave laser beam in the irradiating, at the temperature increased to the range of 600° C. to 800° C.; and increasing a crystal grain size of the crystallized amorphous semiconductor film, as a result of an increase in an in-plane temperature of the crystallized amorphous film to a range of 1100° C. to 1414° C. by latent heat released in the crystallizing of the amorphous semiconductor film irradiated with the continuous-wave laser beam, wherein the light intensity distribution continuously convex upward is defined on the major axis to ensure a certain width of an area included in the amorphous semiconductor film and increased in temperature to the range of 1100° C. to 1414° C. by the latent heat.

According to the present aspect, the amorphous semiconductor film is irradiated with the laser beam so that the temperature of the amorphous semiconductor film is in the range of 600° C. to 800° C. With this irradiation, the temperature of the amorphous semiconductor film is increased to the range of 1100° C. to 1414° C. by the latent heat, and the amorphous semiconductor film is accordingly crystallized. Thus, the amorphous semiconductor film has no area crystallized at a temperature higher than 1414° C. As a result, the crystalline semiconductor film having no surface protrusions and maintaining the surface flatness can be formed. Also, the thin-film transistor having this crystalline semiconductor film can be implemented.

The following is a description of embodiments according to the present invention, with reference to the drawings.

### First Embodiment

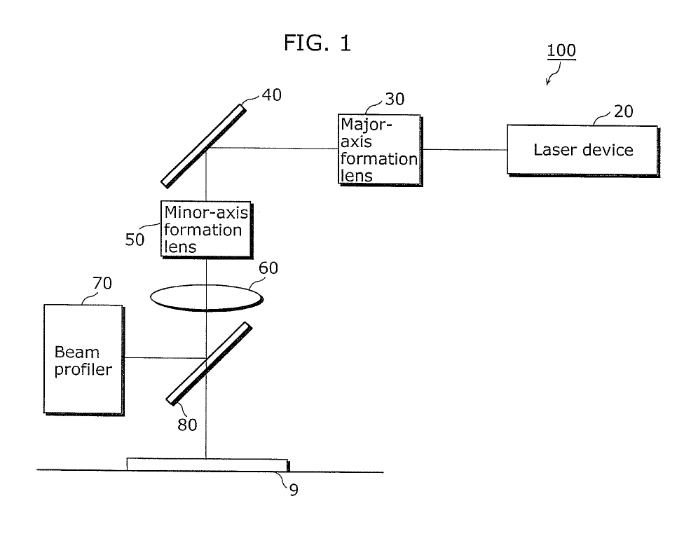

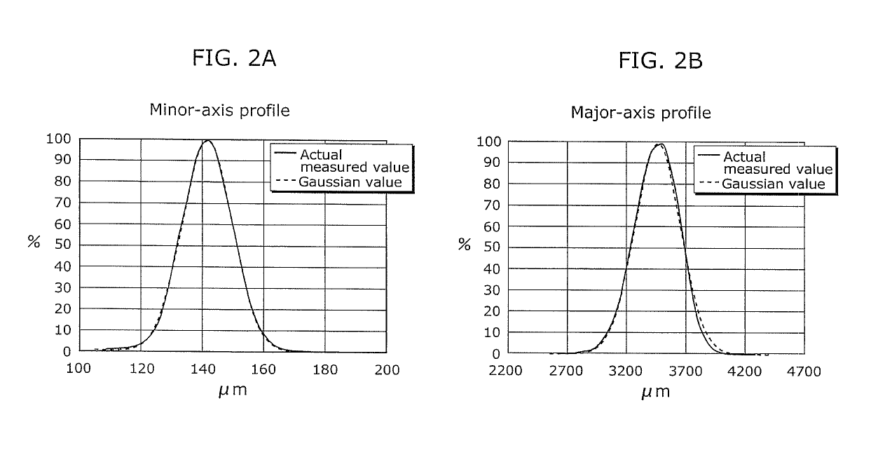

FIG. 1 is a diagram showing an example of a configuration of a CW laser crystallization device in the present embodiment. FIG. 2A is a diagram showing a minor-axis profile of a CW laser beam in the present embodiment. FIG. 2B is a diagram showing a major-axis profile of the CW laser beam in the present embodiment. Hereafter, the direction of the major axis is also referred to as the “longitudinal” direction.

A CW laser crystallization device 100 shown in FIG. 1 emits a CW laser beam onto a sample 9 which is an amorphous semiconductor, such as an amorphous silicon layer, formed on a glass substrate. The sample 9 is irradiated with the CW laser beam for a period of time on the order of microseconds. The CW laser crystallization device 100 includes a laser device 20, a major-axis formation lens 30, a mirror 40, a minor-axis formation lens 50, a condenser lens 60, a beam profiler 70, and a quartz glass 80.

The laser device 20 emits a CW laser beam. The laser device 20 emits, for example, a green laser light or a blue laser light for a relatively long period of time of 10 microseconds to 100 microseconds, instead of a short period of time of 10 nanoseconds to 100 nanoseconds.

In the CW laser crystallization device 100, the CW laser beam emitted from the laser device 20 passes through the major-axis formation lens 30, and a radiation direction of the CW laser beam is changed by the mirror 40. The CW laser beam whose radiation direction has been changed by the mirror 40 passes through the minor-axis formation lens 50, and is collected by the condenser lens 60 to be emitted onto the sample 9. Most of the CW laser beam collected by the condenser lens 60 passes through the quartz glass 80 and then emitted onto the sample. However, a part of the CW laser beam collected by the condenser lens 60 is incident upon the beam profiler 70 where a profile of the beam is measured.

Here, the profile of the CW laser beam collected by the condenser lens 60, that is, the profile of the CW laser beam emitted by the CW laser crystallization device 100 has a Gaussian light intensity distribution, as shown in FIGS. 2A and 2B. Note that each of the vertical axes in FIGS. 2A and 2B indicates a relative intensity with respect to the maximum intensity, represented as 100%, in the laser beam profile shown in corresponding FIG. 2A or 2B.

The beam profile of the CW laser beam collected by the condenser lens 60 has a Gaussian light intensity distribution on each of the minor and major axes. This light intensity distribution results from that the CW laser beam emitted from the laser device 20 passes through the major-axis formation lens 30 and the minor-axis formation lens 50. It should be noted that although the beam profile of the CW laser beam collected by the condenser lens 60 and emitted onto the sample 9 typically has the Gaussian light intensity distribution, the present invention is not limited to this. The profile may have any light intensity distribution as long as the distribution is continuously convex upward.

Here, an intensity distribution of a CW laser beam emitted from a CW laser emitting device is basically a Gaussian distribution or equivalent. This is why the beam profile of the CW laser beam collected by the condenser lens 60 typically has the Gaussian light intensity distribution on each of the minor and major axes. In other words, an optical system of the CW laser crystallization device 100 requires no special additional device or component. Thus, the CW laser crystallization device 100 can relatively easily emit the CW laser beam having the beam profile of the Gaussian light intensity distribution on each of the minor and major axes.

The following is a description of a method to form an amorphous semiconductor into a crystalline semiconductor by irradiating the amorphous semiconductor with the CW laser beam for a period of time on the order of microseconds using the CW laser crystallization device 100 configured as described. For comparison, the case of forming an amorphous semiconductor into a crystalline semiconductor using a conventional CW laser beam is explained as well.

Firstly, an explanation is given about the problem caused in the case of forming the amorphous semiconductor into the crystalline semiconductor using the conventional CW laser beam.

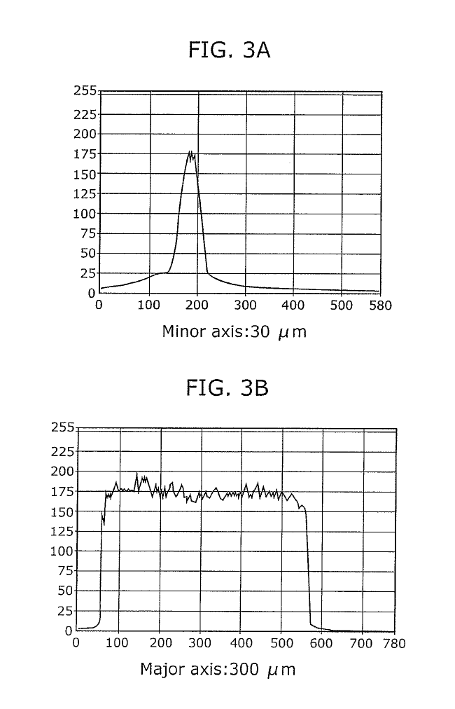

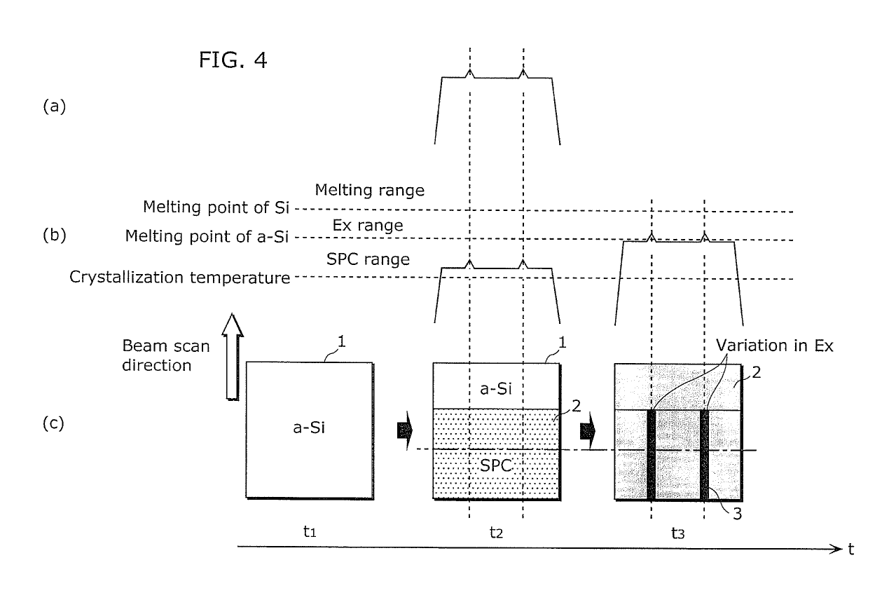

FIG. 3A is a diagram showing a minor-axis profile of the conventional CW laser beam. FIG. 3B is a diagram showing a major-axis profile of the conventional CW laser beam. FIG. 4 is a schematic diagram explaining crystallization performed using the conventional CW laser beam. The horizontal axis in FIG. 4 represents the passage of time. In FIG. 4, (a) shows a section view of a beam profile of the conventional CW laser beam in the major-axis direction. Moreover, (b) of FIG. 4 shows the temperature distribution of a section view of the sample 9 which is an amorphous semiconductor film. Furthermore, (c) of FIG. 4 shows a surface state of the sample 9 which is an amorphous semiconductor film.

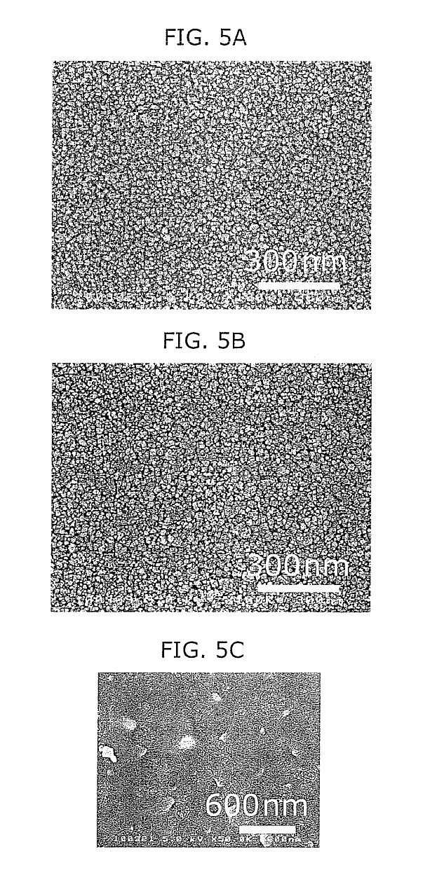

Here, a solid phase crystallization (SPC) range refers to a temperature range of 600° C. to 1100° C. in which an amorphous semiconductor film is crystallized. Note that 1100° C. is the melting point of amorphous silicon. More specifically, SPC is a phenomenon in which the amorphous semiconductor film is crystallized by the solid phase growth mechanism at a temperature in the range of 600° C. to 1100° C. which is the melting point of amorphous silicon. FIG. 5A shows an example of a silicon crystal structure resulting from the SPC process. By the SPC process, the average grain size of silicon crystals is approximately 30 nm, for example, as shown in FIG. 5A and the film surface is flat.

Also, an explosive nucleation (Ex) range refers to a temperature range of 1100° C. to 1414° C. in which an amorphous semiconductor film is crystallized. Note that 1100° C. is the melting point of amorphous silicon and that 1414° C. is the melting point of silicon. More specifically, Ex is a phenomenon in which the amorphous semiconductor film is crystallized, through a supercooled liquid state, at a temperature in the range between 1100° C. that is the melting point of amorphous silicon and 1414° C. that is the melting point of silicon. FIG. 5B shows an example of a silicon crystal structure resulting from the Ex process. By the Ex process, the average grain size of silicon crystals is approximately 40 nm to 50 nm, for example, as shown in FIG. 5B and the film surface is flat.

Moreover, a melting range refers a temperature range higher than the melting point of silicon, that is, 1414° C. FIG. 5C shows an example of a crystal structure which has been melted and then crystallized. Crystallization of amorphous silicon in the melting range results in polycrystalline silicon (P—Si) having the average grain size of approximately 500 nm as shown in FIG. 5C, thereby causing protrusions on the film surface.

As shown in FIGS. 3A and 3B, the conventional CW laser beam has the Gaussian light intensity distribution on the minor axis and the flat-top light intensity distribution on the major axis.

The following describes the case where the sample 9 which is an amorphous semiconductor film is irradiated with this conventional CW laser beam (referred to as the longitudinal flat-top CW laser beam hereafter), with reference to FIG. 4.

Firstly, at a time t1, an amorphous semiconductor film, or more specifically, an amorphous silicon (a-Si) film 1 is prepared as shown in (c) of FIG. 4.

Next, at a time t2, the amorphous silicon film 1 is irradiated with the longitudinal flat-top CW laser beam shown in (a) of FIG. 4. Here, the longitudinal flat-top CW laser beam is continuously emitted in a beam scan direction shown in (c) of FIG. 4. As a result, an area included in the amorphous silicon film 1 and irradiated with the longitudinal flat-top CW laser beam shows the temperature distribution in the SPC range as shown in (b) of FIG. 4. It should be noted that variation in the light intensity is caused in the flat top portion on the major axis of the longitudinal flat-top CW laser beam shown in (a) of FIG. 4. The variation is represented by protrusions on the flat-top portion on the major axis in (a) of FIG. 4.

Then, at a time t3, scanning, namely, irradiation performed on the entire upper surface of the amorphous silicon film 1 with the longitudinal flat-top CW laser beam is completed. Here, as shown in (b) of FIG. 4, the temperature of the amorphous semiconductor film 1 increased by the latent heat of crystallization falls approximately within the SPC range. However, out of the amorphous semiconductor film 1, an area irradiated with the laser beam corresponding to the protrusion part, i.e., the laser beam having the variation in the light intensity, increases in temperature to the Ex range exceeding the SPC range. A crystallization mechanism is different between crystallizations performed in the SPC range and in the Ex range exceeding the SPC range. Therefore, the grain sizes resulting from these different crystallizations are also different. On this account, the area crystallized in the Ex range exceeding the SPC range has resultant variation in the crystal grain size (referred to as the “variation in Ex” hereafter).

As described above, in the case where the amorphous semiconductor film is formed into the crystalline semiconductor film using the conventional longitudinal flat-top CW laser beam, the problem is that the Ex-processed semiconductor film ends up being included in the SPC-processed semiconductor film. That is, the variation in Ex is caused. More specifically, not only that the surface flatness of the crystalline semiconductor film is lost due to, for example, the protrusions on the surface, but also that the in-plane variation is caused to the grain size of the crystalline semiconductor film. This adversely affects the characteristics of the thin-film transistor including this crystalline semiconductor film.

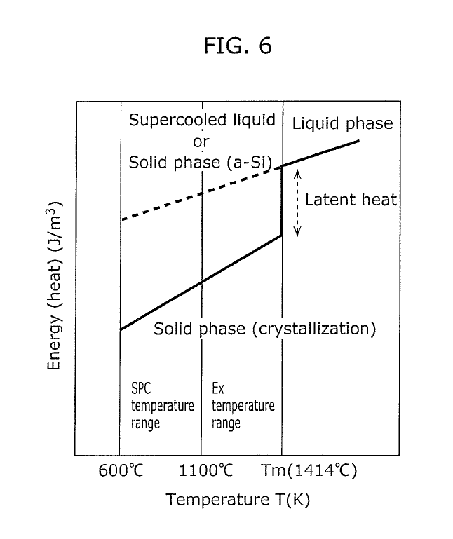

The following describes a crystallization mechanism of silicon with reference to the drawing. FIG. 6 is a diagram showing a relationship between temperature and energy in silicon crystallization. In FIG. 6, the horizontal axis represents temperature and the vertical axis represents energy (heat).

As shown in FIG. 6, suppose that silicon in the amorphous state is heated by, for example, laser irradiation and that the temperature of the silicon reaches a temperature in the SPC range, namely, the range of 600° C. to 1100° C. As a result, the silicon in the amorphous state is micro-crystallized by the solid phase growth mechanism. Note that the average size of crystal grains in the silicon crystallized in the SPC range in this way is from 25 nm to 35 nm.

Moreover, suppose that the silicon in the SPC range is heated so the temperature of the silicon reaches the Ex range, i.e., reaches the temperature which is higher than 1100° C. considered to be the melting point where the an atomic network structure of amorphous silicon changes and which is equal to or lower than 1414° C. that is the melting point of silicon. As a result, the grain size is slightly increased as compared with the size of a crystal obtained by the solid-phase growth mechanism (i.e., the crystal size of the crystalline silicon obtained by the SPC process). The increase in the grain size is thought to result from the fact that the silicon is partially melted at the temperature equal to or higher than the melting point of amorphous silicon. Note that the average size of crystal grains in the silicon crystallized in the Ex range in this way is from 40 nm to 60 nm.

Furthermore, suppose that the silicon in the Ex range is heated so the temperature of the silicon reaches the melting range, that is, reaches the temperature higher than 1414° C. which is the melting point of silicon. As a result, crystals obtained in the Ex range (i.e., the crystals in the crystalline silicon obtained by the Ex process) are exposed to heat energy as latent heat, and thus are melted (i.e., changed into the liquid phase). Note that the silicon in the melting range is once reduced in size in the melting process and then increased in size in the crystallization process to be P—Si with the average grain size of 50 nm or larger.

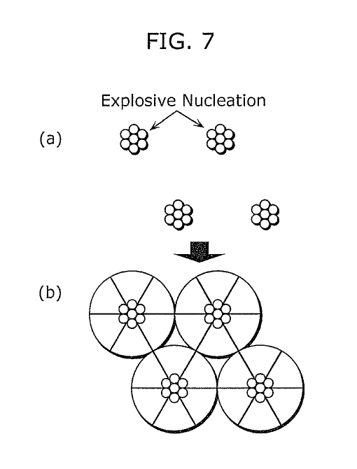

The following describes a melting mechanism of silicon in the Ex range. FIG. 7 is a diagram explaining a growth mechanism of an Ex-processed crystal structure.

A plurality of atoms of silicon in the SPC range are gathered stochastically and, when exceeding a critical grain size (i.e., 1 nm or smaller), become a crystal nucleus in the crystal growth process.

On the other hand, atoms of silicon in the Ex range are exposed to the temperature equal to or higher than the melting point of amorphous silicon and thus are stimulated to move. This encourages formation of crystal nuclei as shown in (a) of FIG. 7. Then, the latent heat melts the perimeters of the grown nuclei, which are accordingly crystallized as shown in (b) of FIG. 7.

In this way, the crystallization mechanism is different among the crystallizations performed in the SPC range, in the Ex range exceeding the SPC range, and in the melting range. Therefore, the resultant grain size is also different for each of these crystallization mechanisms.

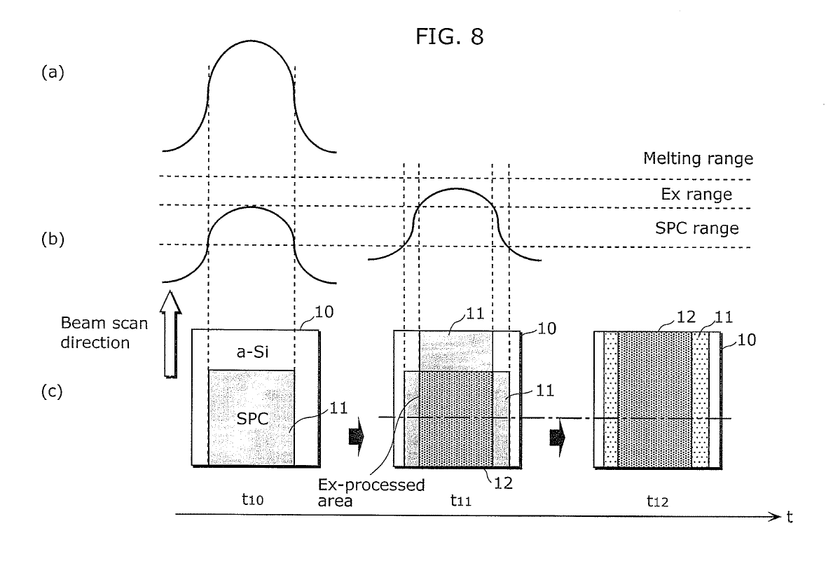

Here, FIG. 8 is a schematic diagram explaining crystallization performed using the CW laser beam in the present embodiment. The horizontal axis in FIG. 8 represents the passage of time. In FIG. 8, (a) shows a section view of a beam profile of the CW laser beam in the major-axis direction. Moreover, (b) of FIG. 8 shows the temperature distribution of a section view of the sample 9 which is an amorphous semiconductor film. Furthermore, (c) of FIG. 8 shows a surface state of the sample 9 which is an amorphous semiconductor film.

Firstly, at a time t10, the sample 9 of an amorphous semiconductor film, or more specifically, an amorphous silicon (a-Si) film 10 is irradiated with the CW laser beam having a Gaussian beam profile on the major axis as shown in (a) of FIG. 8 (this CW laser beam is referred to as the longitudinal Gaussian CW laser beam). Here, the longitudinal Gaussian CW laser beam is continuously emitted in a beam scan direction shown in (c) of FIG. 8 at a power density such that the temperature of the amorphous silicon film 10 is in the range of 600° C. to 1100° C. As a result, an SPC-processed area (shown as an SPC 11 in FIG. 8) included in the amorphous silicon film 10 and irradiated with the longitudinal Gaussian CW laser beam shows the temperature distribution in the SPC range as shown in (b) of FIG. 8. It should be noted that, unlike the longitudinal flat-top CW laser beam, the longitudinal Gaussian CW laser beam shown in (a) of FIG. 8 has no variation in the light intensity.

Next, at a time t11, the amorphous silicon film 10 continues to be irradiated with the longitudinal Gaussian CW laser beam. The irradiation using the longitudinal Gaussian CW laser beam is reaching an end of the amorphous silicon film 10.

Here, the area included in the amorphous silicon film 10 and irradiated with the longitudinal Gaussian CW laser beam at the time 11 is indicated as the SPC 11, as described above. Then, the SPC 11 irradiated with the longitudinal Gaussian CW laser beam at the time t10 is further increased in temperature by the latent heat of crystallization and then becomes an Ex-processed area 12 showing the temperature distribution in the Ex range as shown in (b) of FIG. 8. At the same time, each side area adjacent to the Ex-processed area 12 viewed in the beam scan direction is in the SPC range to be an SPC 11 due to conduction of heat from the Ex-processed area 12. As mentioned above, the temperature in the Ex range refers to a temperature: which is higher than 1100° C. considered to be the melting point that varies depending on the atomic network structure of the amorphous silicon film 10; and which is equal to or lower than 1414° C., i.e., the melting point of silicon.

At a time t12, scanning, namely, irradiation performed on the entire upper surface of the amorphous silicon film 10 with the longitudinal Gaussian CW laser beam is completed. As a result, the SPC 11 irradiated with the longitudinal Gaussian CW laser beam at the time t11 is further increased in temperature by the latent heat of crystallization as with the above, and then becomes an Ex-processed area 12 showing the temperature distribution in the Ex range as shown in (c) of FIG. 8. At the same time, each side area adjacent to the Ex-processed area 12 viewed in the beam scan direction at the time t11 is in the SPC range to be an SPC 11 due to conduction of heat from the Ex-processed area 12.

Here, a width of the Ex-processed area 12 in a direction perpendicular to the beam scan direction, namely, a width of the Ex-processed area 12 in the horizontal direction, corresponds to a width of the longitudinal Gaussian CW laser beam where a light intensity is equal to or higher than a predetermined intensity in the major axis direction. To be more specific, the width where the light intensity is equal to or higher than the predetermined intensity in the major axis direction of the longitudinal Gaussian CW laser beam refers to a width where the power density of the longitudinal Gaussian CW laser beam is such that the temperature of the amorphous silicon film 10 is in the range of 600° C. to 1100° C. (namely, the SPC range).

In the case where the amorphous silicon film 10 is formed into a crystalline silicon film using the longitudinal Gaussian CW laser beam, the area included in the amorphous silicon film 10 and irradiated by the width of the longitudinal Gaussian CW laser beam where the light intensity is equal to or higher than the predetermined intensity is crystallized into the Ex-processed crystalline silicon film. Moreover, each side area adjacent, in the beam scan direction, to the Ex-processed area on the amorphous silicon film 10 irradiated with the longitudinal Gaussian CW laser beam is crystallized into the SPC-processed crystalline silicon film. The grain size of the Ex-processed crystalline silicon film, that is, the grain size of the crystalline silicon film having the Ex-processed crystal structure, is slightly increased as compared with the size of a crystal obtained by the solid phase growth mechanism, and the uniformity is maintained as well. Moreover, no surface protrusions are caused. The average grain size of the Ex-processed crystalline silicon film is 40 nm to 60 nm while maintaining the in-plane uniformity. On the other hand, the average grain size of the SPC-processed crystalline silicon film is 25 nm to 35 nm.

As described, the amorphous semiconductor film is formed into the crystalline semiconductor film by irradiating the amorphous semiconductor film with the longitudinal Gaussian CW laser beam at the power density such that the temperature of the amorphous semiconductor film is in the range of 600° C. to 1100° C. With the irradiation using the longitudinal Gaussian CW laser beam, the temperature of the amorphous semiconductor film is further increased by the latent heat of crystallization. Thus, the temperature of the amorphous semiconductor film exceeds the temperature considered to be the melting point of amorphous silicon that changes the atomic network structure of amorphous silicon, and then reaches a temperature equal to or lower than 1414° C. which is the melting point of crystalline silicon. Following this, the amorphous semiconductor film is crystallized to be the Ex-processed crystalline semiconductor film. In this way, the amorphous semiconductor film irradiated with the longitudinal Gaussian CW laser beam is crystallized and has the resultant grain size slightly increased as compared with the size of a crystal obtained by the solid phase growth mechanism. Also, the uniformity is maintained and no surface protrusions are caused. Here, the average crystal grain size of the crystalline semiconductor film is 40 nm to 60 nm while maintaining the in-plane uniformity.

At the time t10, the amorphous semiconductor film is irradiated with the longitudinal Gaussian CW laser beam at the power density such that the temperature of the amorphous silicon film 10 is in the range of 600° C. to 1100° C. However, the present invention is not limited to this. The same advantageous effect can be achieved in the case where the amorphous semiconductor film is irradiated with the longitudinal Gaussian CW laser beam at the power density such that the temperature of the amorphous silicon film 10 is in the range of 600° C. to 800° C.

As described thus far, the first embodiment can implement the method of manufacturing the Ex-processed crystalline silicon film, that is, the crystalline semiconductor film having the crystal structure with favorable in-plane uniformity.

To be more specific, the amorphous semiconductor film is irradiated with the longitudinal Gaussian CW laser beam for a period of time on the order of microseconds, such as 10 microseconds to 100 microseconds, so that the temperature of the amorphous semiconductor film is in the range of 600° C. to 1100° C. (namely, the SPC range). As a result, the crystalline semiconductor film having the crystal structure with favorable in-plane uniformity can be formed. By irradiating the amorphous semiconductor film with the longitudinal Gaussian CW laser beam to increase the temperature of the amorphous semiconductor film into the SPC range, the temperature of the amorphous semiconductor film stays in the range of 1100° C. to 1414° C. by the latent heat of crystallization. On account of this, crystallization of the irradiated amorphous semiconductor film is performed in the range of 1100° C. to 1414° C., instead of being performed at a temperature higher than 1414° C. Therefore, surface protrusions can be prevented and the surface flatness of the semiconductor film can be maintained. This can enhance the characteristics of the thin-film transistor including the crystalline semiconductor film formed in this way.

Also, the amorphous semiconductor film is irradiated with the longitudinal Gaussian CW laser beam for a period of time on the order of microseconds, instead of the order of nanoseconds. Thus, the irradiation time of the longitudinal Gaussian CW laser beam is longer. This can secure sufficient time for the atoms of the amorphous semiconductor film to rearrange themselves from the amorphous state to crystallize.

Here, there may be a case where an amorphous semiconductor film is formed into a crystalline semiconductor film by irradiating the amorphous semiconductor film with the longitudinal Gaussian CW laser beam at a power density such that the temperature of the irradiated amorphous semiconductor film is instantaneously in the range of 1100° C. to 1414° C. from the very beginning. However, this is inappropriate for the following reason. With the latent heat caused in the irradiated area of the amorphous semiconductor film, the area is melted at the temperature exceeding 1414° C. and then crystallized. When the amorphous semiconductor film is crystallized after being melted at the temperature higher than 1414° C., the amorphous semiconductor film is once reduced in size in the melting process and then increased in size in the crystallization process. Thus, the film may not only have a surface protrusion identical in length to the thickness of the amorphous semiconductor film but also have a large variation in the grain size. For this reason, the case of irradiating, from the very beginning, the amorphous semiconductor film with the laser beam at the power intensity such that the temperature of the amorphous semiconductor film is instantaneously in the range of 1100° C. to 1414° C. cannot implement the method of manufacturing the crystalline semiconductor film having the crystal structure with favorable in-plane uniformity. In other words, the present case is inappropriate.

### Second Embodiment

The second embodiment describes an example of the application of the crystalline semiconductor film having the crystal structure with favorable in-plane uniformity that is manufactured according to the method in the first embodiment.

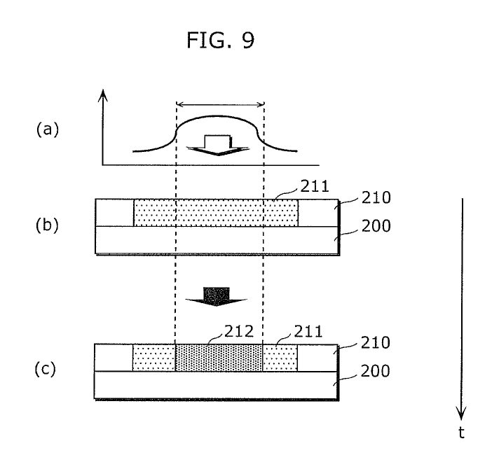

FIG. 9 is a diagram explaining an example of the application of the crystalline semiconductor film to a substrate, in the present embodiment.

Firstly, a substrate coated with an amorphous semiconductor film and a longitudinal Gaussian CW laser beam are prepared. The substrate is configured with a base material 200 and an amorphous semiconductor film 210 which is formed on the base material 200. Here, a beam profile of the longitudinal Gaussian CW laser beam has a Gaussian light intensity distribution as shown in (a) of FIG. 9.

Next, the amorphous semiconductor film 210 is irradiated with the longitudinal Gaussian CW laser beam for a period of time on the order of microseconds. To be more specific, the amorphous semiconductor film 210 is irradiated with the longitudinal Gaussian CW laser beam so that the temperature of the amorphous semiconductor film 210 is in the range of 600° C. to 800° C. (i.e., the SPC range).

As a result, as shown in (b) of FIG. 9, the area irradiated with the longitudinal Gaussian CW laser beam is formed into an SPC-processed crystalline semiconductor film 211. Here, the SPC-processed crystalline semiconductor film 211 is a crystalline semiconductor film having a crystal structure (or, a crystal grain) crystallized by the solid phase growth mechanism in the SPC range of 600° C. to 1100° C., as described above.

At the conclusion of a predetermined elapsed time after the completion of the irradiation using the longitudinal Gaussian CW laser beam, an area included in the SPC-processed crystalline semiconductor film 211 and irradiated with the longitudinal Gaussian CW laser beam is increased in temperature to the Ex range by the latent heat of crystallization. This results in an increase in the crystal grain size and in an Ex-processed crystalline semiconductor film 212, as shown in (c) of FIG. 9.

Here, a width of the Ex-processed crystalline semiconductor film 212, which is included in the SPC-processed crystalline semiconductor film 211, corresponds to a width of the longitudinal Gaussian CW laser beam where the light intensity is equal to or higher than a predetermined intensity in the major axis direction.

In this way, the substrate coated with the crystalline semiconductor film having the crystal structure with favorable in-plane uniformity can be implemented using the longitudinal Gaussian CW laser beam.

It should be noted that the crystalline semiconductor film having the crystal structure with favorable in-plane uniformity that is manufactured using the longitudinal Gaussian CW laser beam is not limited to the above example and can be applied to a bottom-gate thin-film transistor.

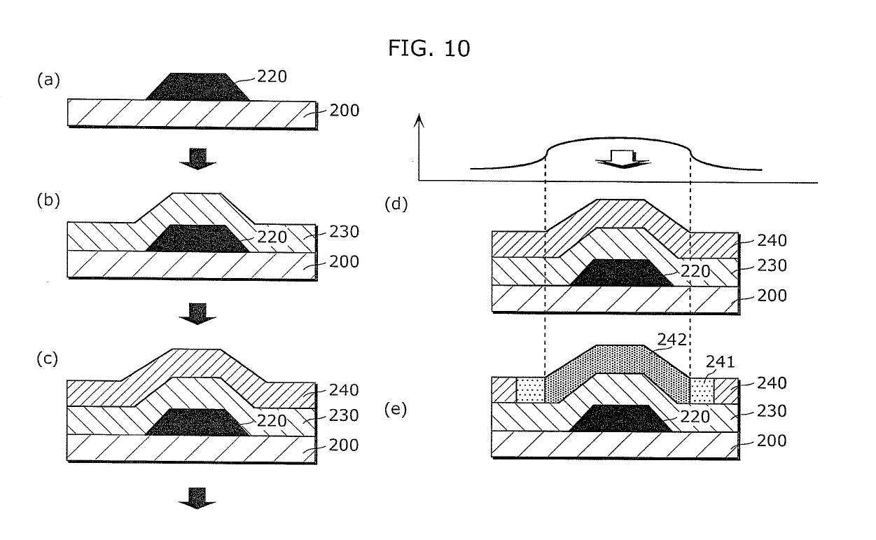

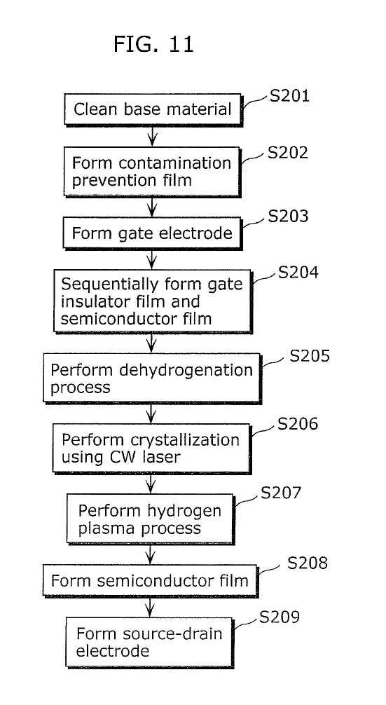

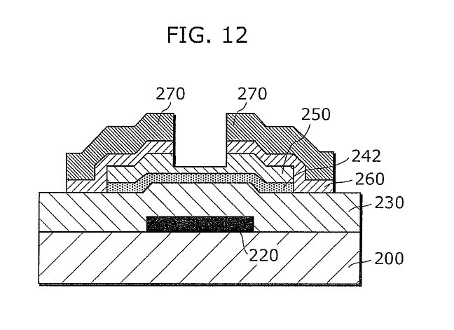

FIG. 10 is a diagram explaining a method of manufacturing a bottom-gate thin-film transistor in the present embodiment. FIG. 11 is a flowchart explaining the method of manufacturing the bottom-gate thin-film transistor in the present embodiment. FIG. 12 is a diagram showing a configuration of the bottom-gate thin-film transistor including the crystalline semiconductor film, in the present embodiment.

Firstly, a base material 200, such as a glass substrate or an insulating substrate, is prepared. Next, the base material 200 is cleaned (S201), and then a contamination prevention film is formed on the base material 200 (S202).

Then, as shown in (a) in FIG. 10, a gate electrode 220 is formed on the base material 200 (S203). To be more specific, metal used for forming the gate electrode 220 is deposited on the base material 200 by the sputtering method, and then the gate electrode 220 is formed by a patterning process such as a photolithography or etching process. For example, the gate electrode 220 is formed from a metallic material including: metal such as molybdenum (Mo) or Mo alloy; metal such as titanium (Ti), aluminium (Al), or Al alloy: metal such as copper (Cu) or Cu alloy; or metal such as silver (Ag), chromium (Cr), tantalum (Ta), or tungsten (W).

Following this, a gate insulating film 230 is formed on the gate electrode 220 as shown in (b) of FIG. 10, and then an amorphous semiconductor film 240 which is, for example, an amorphous silicon film is formed on the gate insulating film 230 as shown in (c) of FIG. 10 (S204). More specifically, in (b) of FIG. 10, the gate insulating film 230 is formed on the gate electrode 220 to cover both the base material 200 and the gate electrode 220, using a plasma chemical vapor deposition (plasma CVD) technique. Then, in (c) of FIG. 10, the amorphous semiconductor film 240 is seamlessly formed on the gate insulating film 230.

Next, a dehydrogenation process is performed as a preliminary preparation for irradiating the amorphous semiconductor film with the longitudinal Gaussian CW laser beam (S205). To be more specific, annealing is performed at a temperature between 400° C. and 500° C. for 30 minutes. In general, the amorphous semiconductor film 240 has a hydrogen content of 5% to 15%, as hydrogenated silicon (Si:H). When crystallization is performed on the amorphous semiconductor film 240 having a hydrogen content of 5% to 15%, the hydrogen interferes with silicon and ends up inhibiting crystallization. Also, a sudden explosive boil or the like is more likely to occur. In other words, such an amorphous semiconductor film is undesirable for process control and, for this reason, the dehydrogenation process is performed.

Then, the amorphous semiconductor film 240 is irradiated with the longitudinal Gaussian CW laser beam as shown in (d) of FIG. 10, and then the amorphous semiconductor film 240 is crystallized as shown in (e) of FIG. 10 (S206). To be more specific, an area included in the amorphous semiconductor film 240 and irradiated with the longitudinal Gaussian CW laser beam by a longitudinal width where the light intensity is equal to or higher than a predetermined intensity is formed into an Ex-processed crystalline semiconductor film 242. Also, an area adjacent to the EX-processed crystalline semiconductor film 242 is formed into an SPC-processed crystalline semiconductor film 241. On the other hand, an area included in the amorphous semiconductor film 240 and hardly irradiated with the longitudinal Gaussian CW laser beam remains as the amorphous semiconductor film 240. Here, the longitudinal width of the longitudinal Gaussian CW laser beam where the light intensity is equal to or higher than the predetermined intensity is wider than at least a width of the gate electrode 220 (i.e., the width in a direction perpendicular to the longitudinal direction of the CW laser beam). The irradiation method using the longitudinal Gaussian CW laser beam has been explained in detail above and, therefore, the explanation is not repeated here.

Next, a hydrogen plasma process is performed (S207). More specifically, a hydrogen termination process is performed, via this hydrogen plasma process, on the amorphous semiconductor film 240 irradiated with the longitudinal Gaussian CW laser beam. That is to say, the hydrogen termination process is performed on the amorphous semiconductor film 240, the SPC-processed crystalline semiconductor film 241, and the Ex-processed crystalline semiconductor film 242.

Following this, a semiconductor film 250 is formed (S208). To be more specific, the semiconductor film 250 is formed on the amorphous semiconductor film 240, the SPC-processed crystalline semiconductor film 241, and the Ex-processed crystalline semiconductor film 242, using the plasma CVD technique. Then, the patterning process is performed in such a way to keep the Ex-processed crystalline semiconductor film 242 as it is, and the etching process is performed to remove a part of the semiconductor film 250 and the remaining amorphous semiconductor film 240 and SPC-processed semiconductor film 241. As a result, only the crystalline semiconductor film having the crystal structure with favorable in-plane uniformity can be formed as a channel part of the bottom-gate thin-film transistor.

Next, a source-drain electrode 270 is formed (S210). More specifically, metal used for forming the source-drain electrode 270 is deposited on the semiconductor film 250 by the sputtering method. Following this, the patterning process is performed to form the source-drain electrode 270. Here, the semiconductor film 250 serves as an ohmic contact layer connecting the Ex-processed crystalline semiconductor film 242 and the source-drain electrode 270.

In this way, the bottom-gate thin-film transistor shown in FIG. 12 is manufactured.

It should be noted that although the method of manufacturing a single bottom-gate thin-film transistor has been described for convenience of explanation, the present invention is not limited to this. A plurality of bottom-gate thin-film transistors may be manufactured at one time.

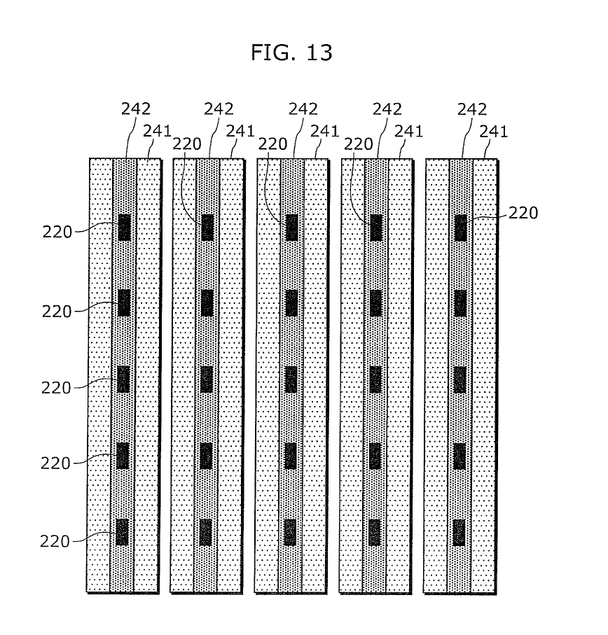

FIG. 13 is a diagram explaining the case where the plurality of bottom-gate thin-film transistors are manufactured at one time.

In the case where the plurality of bottom-gate thin-film transistors are manufactured at one time, a plurality of gate electrodes 220 are formed on the base material 200 at predetermined intervals and the gate insulating film 230 is formed over these gate electrodes 220, in S201 to S205 described above. Here, the gate electrodes 220 may be arranged at the predetermined intervals in a row, and such rows may also be arranged at predetermined intervals. FIG. 13 shows the latter case as an example.

Then, in S206, an area which is included in the amorphous semiconductor film 240 and positionally corresponds to the gate electrodes 220 arranged at the predetermined intervals in a row is continuously irradiated with the longitudinal Gaussian CW laser beam, as shown in FIG. 13. Hereafter, this area of the amorphous semiconductor film 240 is referred to as the belt-like area. Thus, the belt-like area of the amorphous semiconductor film 240 is crystallized. Here, a longitudinal width of the longitudinal Gaussian CW laser beam where the light intensity is equal to or higher than a predetermined intensity is wider than a width of the belt-like area of the amorphous semiconductor film 240. Note that the width of the belt-like area of the amorphous semiconductor film 240 refers to a width in a direction perpendicular to the scan direction of the longitudinal Gaussian CW laser beam.

As described, the belt-like area included in the amorphous semiconductor film 240 is continuously irradiated with the longitudinal Gaussian CW laser beam. Here, the area where the gate electrodes 220 are arranged at the predetermined intervals positionally corresponds to the belt-like area whose width is wider than each width of the gate electrodes 220 in the direction perpendicular to the arrangement direction of the gate electrodes 220. As a result of the irradiation, the belt-like area which positionally corresponds to the gate electrodes 220 can be formed into an Ex-processed crystalline semiconductor film 242. Also, as with the above, an area adjacent to the EX-processed crystalline semiconductor film 242 in the direction perpendicular to the scan direction of the longitudinal Gaussian CW laser beam is formed into an SPC-processed crystalline semiconductor film 241.

In this way, the width of the Gaussian CW laser beam in the major axis direction matches with the width of the belt-like area which is included in the amorphous semiconductor film and positionally corresponds to the gate electrodes arranged at the predetermined intervals. Thus, the belt-like area can be selectively irradiated, out of the amorphous semiconductor film. Accordingly, the area included in the crystalline semiconductor film and formed as a channel part of the thin-film transistor can be selectively micro-crystallized. In addition, the crystalline semiconductor film having a flat surface can be formed.

It should be noted that the Ex-processed crystalline semiconductor film 242 is formed from crystal grains whose average size is 40 nm to 60 nm, and is also formed in the shape of a belt covering the area which positionally corresponds to the gate electrodes 220 arranged at the predetermined intervals in a row. Moreover, the SPC-processed crystalline semiconductor film 241 is formed adjacent to the Ex-processed crystalline semiconductor film 242. The base material 200 including this crystalline semiconductor film has an advantageous effect of being easily divided into multiple pieces along the aforementioned belt-like area according to the dicing method or the like.

As described thus far, the second embodiment can implement: the bottom-gate thin-film transistor to which the crystalline semiconductor film having the crystal structure with favorable in-plane uniformity is applied; and the substrate coated with the crystalline semiconductor film.

### Third Embodiment

In the second embodiment, the bottom-gate thin-film transistor and the substrate coated with the crystalline semiconductor film are described as the application examples. The third embodiment describes a top-gate thin-film transistor as an application example.

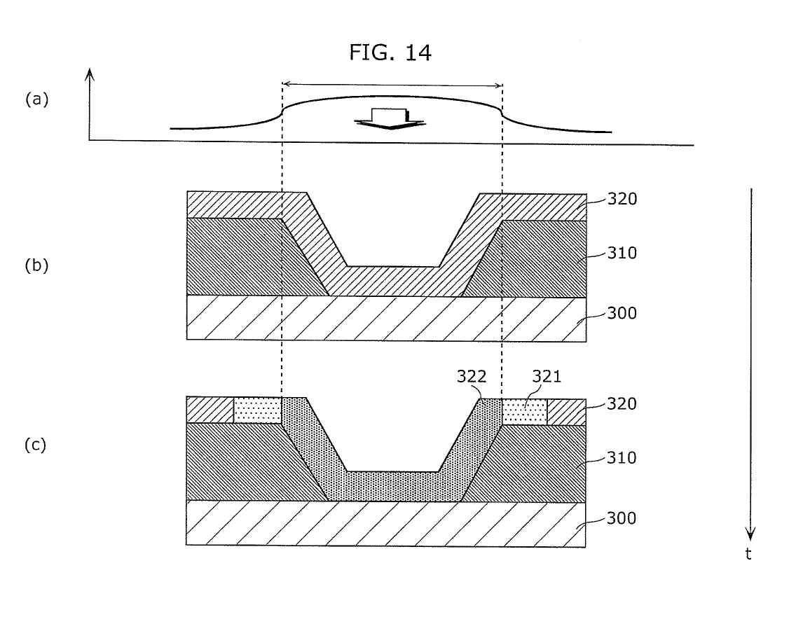

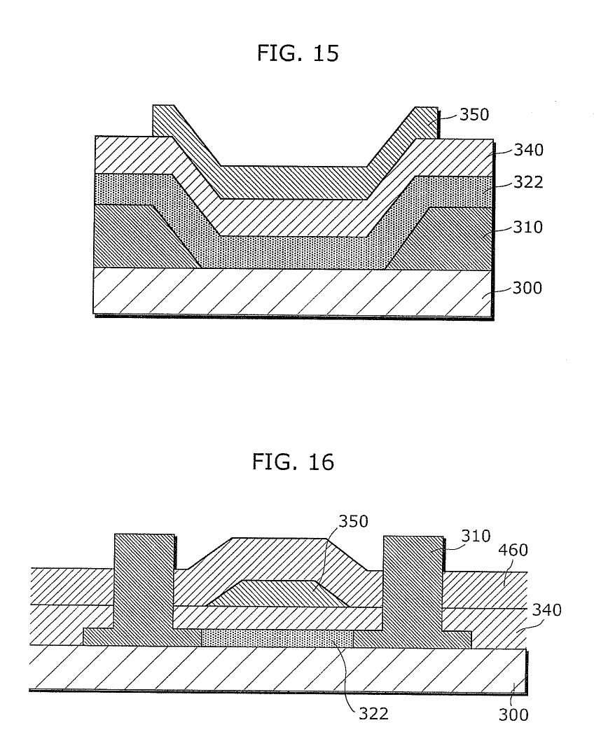

FIG. 14 is a diagram explaining a method of manufacturing the top-gate thin-film transistor in the present embodiment. FIG. 15 is a diagram showing a configuration of the top-gate thin-film transistor in the present embodiment.

FIG. 14 shows a part of the process of manufacturing the top-gate thin-film transistor.

More specifically, (b) in FIG. 14 shows a manufacturing process of forming a source-drain electrode 310 on a base substrate 300 and then forming an amorphous semiconductor film 320 on the source-drain electrode 310. Following this, the amorphous semiconductor film 320 is irradiated with a longitudinal Gaussian CW laser beam shown in (a) of FIG. 14, and is then crystallized as shown in (c) of FIG. 14.

To be more specific, out of the amorphous semiconductor film 320, an area which is to be a gate is irradiated with the longitudinal Gaussian CW laser beam by a longitudinal width where the light intensity is equal to or higher than a predetermined intensity.

As a result, the area included in the amorphous semiconductor film 320 and irradiated with the longitudinal Gaussian CW laser beam by the longitudinal width where the light intensity is equal to or higher than the predetermined intensity is formed into an Ex-processed crystalline semiconductor film 322. Also, an area adjacent to the EX-processed crystalline semiconductor film 322 is formed into an SPC-processed crystalline semiconductor film 321. On the other hand, an area included in the amorphous semiconductor film 320 and hardly irradiated with the longitudinal Gaussian CW laser beam remains as the amorphous semiconductor film 320. The details of the irradiation method using the longitudinal Gaussian CW laser beam are the same as those explained above and, therefore, the explanation is not repeated here.

Accordingly, the top-gate thin-film transistor having the Ex-processed crystalline semiconductor film 322, as shown in FIG. 15 as an example, can be formed. The top-gate thin-film transistor shown in FIG. 15 includes the base material 300, the source-drain electrode 310, the Ex-processed crystalline semiconductor film 322, a gate insulating film 340 formed on the Ex-processed crystalline semiconductor film 322, and a gate electrode 350 formed on the gate insulating film 340.

The configuration of the top-gate thin-film transistor is not limited to the one shown in FIG. 15, and may be the one shown in FIG. 16 for example. FIG. 16 is a diagram showing another configuration of a top-gate thin-film transistor in the third embodiment. In FIG. 16, components identical to those in FIG. 15 are assigned the same numerals as used in FIG. 15. It should be noted that, in FIG. 15, a protection film 460 formed on the gate electrode 350 of the top-gat thin-film transistor is illustrated.

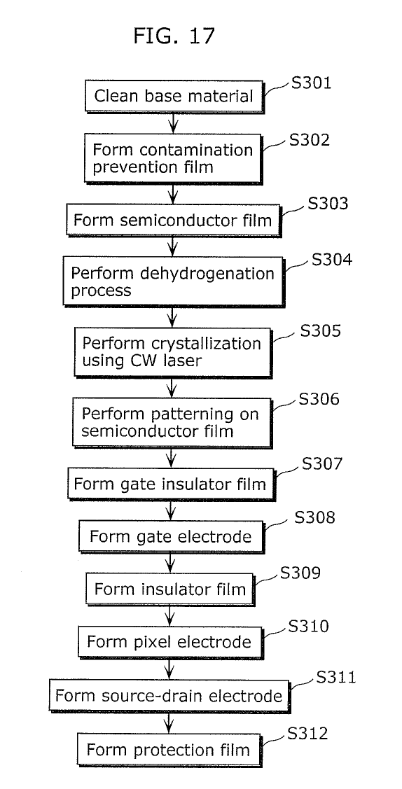

FIG. 17 is a flowchart explaining the method of manufacturing the top-gate thin-film transistor in the present embodiment.

Processes S301 to S311 are identical to the processes S201 to S209, except for the order in which the source-drain electrode 310 and the gate electrode 350 are formed. Also, a process performed in S305 has been explained with reference to FIG. 14 and, thus, the explanation is omitted here. It should be noted that, in S312, a protection film such as the protection film 460 is formed on the gate electrode 350.

Also, it should be obvious that the top-gate thin-film transistor in each of FIGS. 16 and 17 in the present embodiment may be manufactured in multiple at one time as in the case of the second embodiment. In this case, a plurality of source-drain electrodes 310 are formed on the base substrate 300 at predetermined intervals and the gate insulating film 340 is formed over the gate electrodes 350, in S301 to S303. Here, the source-drain electrodes 310 may be arranged at the predetermined intervals in a row, and such rows may also be arranged at predetermined intervals.

Then, an area (i.e., a belt-like area) which is included in the amorphous semiconductor film and positionally corresponds to the gate electrodes 350 formed between the source-drain electrodes 310 arranged at the predetermined intervals is continuously irradiated with the longitudinal Gaussian CW laser beam. As a result, out of the amorphous semiconductor film, the belt-like area which positionally corresponds to the gate electrodes 350 can be formed into an EX-processed crystalline semiconductor film 322.

It should be noted that the Ex-processed crystalline semiconductor film 322 is formed from crystal grains whose average size is 40 nm to 60 nm, and is also formed in the shape of a belt covering the area where the gate electrodes 350 are arranged at the predetermined intervals in a row. Moreover, the SPC-processed crystalline semiconductor film 321 is formed adjacent to the Ex-processed crystalline semiconductor film 322. The base material 300 including this crystalline semiconductor film has an advantageous effect of being easily divided into multiple pieces along the aforementioned belt-like area according to the dicing method or the like.

As described thus far, the third embodiment can implement the top-gate thin-film transistor to which the crystalline semiconductor film having the crystal structure with favorable in-plane uniformity is applied.

As described above, the amorphous semiconductor film is irradiated with the CW laser beam having the Gaussian distributions in the directions of the major and minor axes so that the temperature of the amorphous semiconductor film is in the range of 600° C. to 800° C. (i.e., the SPC range). Then, the temperature of the amorphous semiconductor film reaches the range of 1100° C. to 1414° C. (i.e., the Ex range) by the latent heat. After this, the amorphous semiconductor film is crystallized. This method causes no area in the amorphous semiconductor film that is crystallized after exceeding 1414° C. (that is, the melting range). Thus, the crystalline semiconductor film having no surface protrusions and maintaining the surface flatness can be formed. In this way, not only the crystalline semiconductor film having no surface protrusions and maintaining the surface flatness can be formed, but also the thin-film transistor having this crystalline semiconductor film can be implemented.

According to the present invention described thus far, the amorphous semiconductor film is irradiated with the CW laser beam having a longitudinal light intensity gradient, such as a Gaussian distribution, for a period of time on the order of microseconds. As a result of this irradiation, the amorphous semiconductor film is crystallized. Here, using the latent heat effect, the amorphous semiconductor film is crystallized in the temperature range between the melting point of the amorphous semiconductor film and the crystalline melting point. With this, in-plane variation in the grain size of the formed crystalline semiconductor film is prevented, and also the grain size of the crystal structure is increased as compared with the size of a crystal obtained by the solid phase growth mechanism. Thus, the present invention can provide the method of manufacturing the crystalline semiconductor film having the crystal structure with favorable in-plane uniformity, the method of manufacturing the substrate coated with the crystalline semiconductor film, and the thin-film transistor.

Also, the crystalline semiconductor film including the Ex-processed crystal structure which is superior to the SPC-processed crystal structure in electrical characteristics and which has a microcrystal structure with favorable in-plane uniformity can be formed. This can implement a thin-film transistor with less characteristic variation and a display device using this thin-film transistor.

The average size of crystal grains in the Ex-processed crystalline semiconductor film is 40 nm to 60 nm. On this account, a top-gate thin-film transistor manufactured using such an Ex-processed crystalline semiconductor film has an advantageous effect of securing the mobility to obtain adequate ON characteristics as the thin-film transistor to be used for an organic EL display device.

It should be noted that the crystalline semiconductor film may be formed only from an Ex-processed crystalline semiconductor film or may be formed from mixed amorphous and Ex-processed crystals. In such a case, the crystalline semiconductor film includes a mixed amorphous-crystalline crystal. That is, the mixed crystal includes a crystal grain with the average size of 40 nm to 60 nm and an amorphous area around the crystal gain. Such an amorphous structure can reduce crystallographic unconformity at an interface between adjacent crystal grains of the crystalline semiconductor film.

Although the method of manufacturing the crystalline semiconductor film, the method of manufacturing the substrate coated with the crystalline semiconductor film, and the thin-film transistor according to the present invention have been described on the basis of the above embodiments, the present invention is not limited to these embodiments. It should be obvious that changes and modifications conceived by those skilled in the art may be appropriately made to each of the embodiments and that the features of the embodiments may be appropriately combined. Therefore, as long as these changes, modifications, and combinations do not depart from the spirit of the present invention, they are intended to be included in the scope of the present invention.

### INDUSTRIAL APPLICABILITY

The present invention can be used for a method of manufacturing a crystalline semiconductor film, a method of manufacturing a substrate coated with a crystalline semiconductor film, and a thin-film transistor. In particular, the present invention can be used for forming a channel part of a thin-film transistor in an organic EL display device used as a flat panel display (FPD) device, such as a TV.

What is claimed is:

1. A method of manufacturing a crystalline semiconductor film, said method comprising:
irradiating an amorphous semiconductor film with a continuous-wave laser beam to increase a temperature of the amorphous semiconductor film to a range of 600° C. to 1100° C., the continuous-wave laser beam having a light intensity distribution which is continuously convex upward on each of major and minor axes;
crystallizing the amorphous semiconductor film irradiated with the continuous-wave laser beam in said irradiating, at the temperature increased to the range of 600° C. to 1100° C.; and
increasing a crystal grain size of the crystallized amorphous semiconductor film, as a result of an increase in an in-plane temperature of the crystallized amorphous film to a range of 1100° C. to 1414° C. by latent heat released in said crystallizing of the amorphous semiconductor film irradiated with the continuous-wave laser beam,
wherein the light intensity distribution continuously convex upward has a width where a light intensity is equal to or higher than a predetermined intensity in a major axis direction, and
the width corresponds to a width of an area included in the amorphous semiconductor film and increased in temperature to the range of 1100° C. to 1414° C. by the latent heat.

2. The method of manufacturing a crystalline semiconductor film according to claim 1,
wherein the light intensity distribution which is continuously convex upward is a Gaussian distribution.

3. The method of manufacturing a crystalline semiconductor film according to claim 1,
wherein, in said irradiating, the amorphous semiconductor film is irradiated with the continuous-wave laser beam so that the temperature of the amorphous semiconductor film is in a range of 600° C. to 800° C.

4. The method of manufacturing a crystalline semiconductor film according to claim 1,
wherein, in said irradiating, the amorphous semiconductor film is irradiated with the continuous-wave laser beam for a period of time on the order of microseconds.

5. The method of manufacturing a crystalline semiconductor film according to claim 4,
wherein, in said irradiating, the amorphous semiconductor film is irradiated with the continuous-wave laser beam for 10 microseconds to 100 microseconds.

6. The method of manufacturing a crystalline semiconductor film according to claim 1, said method further comprising, prior to said irradiating:
preparing a base material;
arranging a plurality of gate electrodes at predetermined intervals above the base material;
forming an insulating film over the gate electrodes arranged at the predetermined intervals; and
forming the amorphous semiconductor film on the insulating film,
wherein a certain width of the light intensity distribution is defined in the major axis direction to increase, to the range of 1100° C. to 1414° C. by the latent heat, a temperature of the area which is included in the amorphous semiconductor film and positionally corresponds to the gate electrodes arranged at the predetermined intervals.

7. The method of manufacturing a crystalline semiconductor film according to claim 6,
wherein the width of the area which is included in the amorphous semiconductor film and positionally corresponds to the gate electrodes arranged at the predetermined intervals is wider than a width of each of the gate electrodes.

8. A substrate coated with a crystalline semiconductor film, said substrate comprising:
a base material;
a plurality of gate electrodes arranged above said base material;
an insulating film formed over said gate electrodes; and
a crystalline semiconductor film formed to cover said insulating film formed over the gate electrodes arranged above said base material,
wherein said crystalline semiconductor film includes:
a first area formed from crystal grains with an average size of 40 nm to 60 nm and seamlessly formed over an area where said gate electrodes are arranged; and
a second area formed from crystal grains with an average size of 25 nm to 35 nm and located adjacent to the first area.

9. The substrate coated with the crystalline semiconductor film according to claim 8,
wherein said crystalline semiconductor film includes a mixed amorphous-crystalline crystal.

10. The substrate coated with the crystalline semiconductor film according to claim 8,
wherein said gate electrodes are arranged in a row, above said base material, and
the first area included in said crystalline semiconductor film and formed from the crystal grains with the average size of 40 nm to 60 nm is in a seamless belt-like shape and formed over the area where said gate electrodes are arranged in the row.

11. The substrate coated with the crystalline semiconductor film according to claim 8,
wherein the first area included in said crystalline semiconductor film and formed from the crystal grains with the average size of 40 nm to 60 nm is formed by:
irradiating an amorphous semiconductor film with a continuous-wave laser beam to increase a temperature of the amorphous semiconductor film to a range of 600° C. to 800° C., the continuous-wave laser beam having a light intensity distribution which is continuously convex upward on each of major and minor axes;
crystallizing the amorphous semiconductor film irradiated with the continuous-wave laser beam in said irradiating, at the temperature increased to the range of 600° C. to 800° C.; and
increasing a crystal grain size of the crystallized amorphous semiconductor film, as a result of an increase in an in-plane temperature of the crystallized amorphous film to a range of 1100° C. to 1414° C. by latent heat released in said crystallizing of the amorphous semiconductor film irradiated with the continuous-wave laser beam,
wherein the light intensity distribution continuously convex upward is defined on the major axis to ensure a certain width of an area included in the amorphous semiconductor film and increased in temperature to the range of 1100° C. to 1414° C. by the latent heat, and
the area included in the amorphous semiconductor film and increased in temperature to the range of 1100° C. to 1414° C. by the latent heat corresponds to the first area.

12. A bottom-gate thin-film transistor comprising:
a gate electrode;
an insulating film formed on said gate electrode;
a crystalline semiconductor film formed on said insulating film; and
a source-drain electrode formed on said crystalline semiconductor film,
wherein said crystalline semiconductor film is formed from crystal grains with an average size of 40 nm to 60 nm, and
each of the crystal grains are formed by:
irradiating an amorphous semiconductor film with a continuous-wave laser beam to increase a temperature of the amorphous semiconductor film to a range of 600° C. to 800° C., the continuous-wave laser beam having a light intensity distribution which is continuously convex upward on each of major and minor axes;
crystallizing the amorphous semiconductor film irradiated with the continuous-wave laser beam in said irradiating, at the temperature increased to the range of 600° C. to 800° C.; and
increasing a crystal grain size of the crystallized amorphous semiconductor film, as a result of an increase in an in-plane temperature of the crystallized amorphous film to a range of 1100° C. to 1414° C. by latent heat released in said crystallizing of the amorphous semiconductor film irradiated with the continuous-wave laser beam,
wherein the light intensity distribution continuously convex upward is defined on the major axis to ensure a certain width of an area included in the amorphous semiconductor film and increased in temperature to the range of 1100° C. to 1414° C. by the latent heat.

13. A substrate coated with a crystalline semiconductor film, said substrate comprising:
a base material;
a plurality of source-drain electrodes arranged above said base material;
an insulating film formed over the source-drain electrodes; and
a crystalline semiconductor film formed to cover said insulating film formed over the source-drain electrodes arranged above said base material,
wherein said crystalline semiconductor film includes:
a first area formed from crystal grains with an average size of 40 nm to 60 nm and seamlessly formed over an area where said source-drain electrodes are arranged; and
a second area formed from crystal grains with an average size of 25 nm to 35 nm and located adjacent to the first area.

14. The substrate coated with the crystalline semiconductor film according to claim 13,
wherein said crystalline semiconductor film includes a mixed amorphous-crystalline crystal.

15. The substrate coated with the crystalline semiconductor film according to claim 13,
wherein said gate electrodes are arranged in a row, above said base material, and
the first area included in said crystalline semiconductor film and formed from the crystal grains with the average size of 40 nm to 60 nm is in a seamless belt-like shape and formed over the area where said gate electrodes are arranged in the row.

16. The substrate coated with the crystalline semiconductor film according to claim 13,
wherein the first area included in said crystalline semiconductor film and formed from the crystal grains with the average size of 40 nm to 60 nm is formed by:
irradiating an amorphous semiconductor film with a continuous-wave laser beam to increase a temperature of the amorphous semiconductor film to a range of 600° C. to 800° C., the continuous-wave laser beam having a light intensity distribution which is continuously convex upward on each of major and minor axes;
crystallizing the amorphous semiconductor film irradiated with the continuous-wave laser beam in said irradiating, at the temperature increased to the range of 600° C. to 800° C.; and
increasing a crystal grain size of the crystallized amorphous semiconductor film, as a result of an increase in an in-plane temperature of the crystallized amorphous film to a range of 1100° C. to 1414° C. by latent heat released in said crystallizing of the amorphous semiconductor film irradiated with the continuous-wave laser beam,
wherein the light intensity distribution continuously convex upward is defined on the major axis to ensure a certain width of an area included in the amorphous semiconductor film and increased in temperature to the range of 1100° C. to 1414° C. by the latent heat, and
the area included in the amorphous semiconductor film and increased in temperature to the range of 1100° C. to 1414° C. by the latent heat corresponds to the first area.

17. A top-gate thin-film transistor comprising:
a source-drain electrode;
a crystalline semiconductor film formed on said source-drain electrode;
an insulating film formed on said crystalline semiconductor film; and
a gate electrode formed on said insulating film,
wherein said crystalline semiconductor film is formed from crystal grains with an average size of 40 nm to 60 nm, and
each of the crystal grains are formed by:
irradiating an amorphous semiconductor film with a continuous-wave laser beam to increase a temperature of the amorphous semiconductor film to a range of 600° C. to 800° C., the continuous-wave laser beam having a light intensity distribution which is continuously convex upward on each of major and minor axes;
crystallizing the amorphous semiconductor film irradiated with the continuous-wave laser beam in said irradiating, at the temperature increased to the range of 600° C. to 800° C.; and
increasing a crystal grain size of the crystallized amorphous semiconductor film, as a result of an increase in an in-plane temperature of the crystallized amorphous film to a range of 1100° C. to 1414° C. by latent heat released in said crystallizing of the amorphous semiconductor film irradiated with the continuous-wave laser beam,
wherein the light intensity distribution continuously convex upward is defined on the major axis to ensure a certain width of an area included in the amorphous semiconductor film and increased in temperature to the range of 1100° C. to 1414° C. by the latent heat.

18. A method of manufacturing a crystalline semiconductor film, said method comprising:
irradiating an amorphous semiconductor film with a continuous-wave laser beam to increase a temperature of the amorphous semiconductor film to a first temperature which is lower than a melting point of the amorphous semiconductor film and at which the amorphous semiconductor film is crystallized by a solid phase growth mechanism, the continuous-wave laser beam having a light intensity distribution which is continuously convex upward on each of major and minor axes;
crystallizing the amorphous semiconductor film irradiated with the continuous-wave laser beam in said irradiating, at the first temperature; and
increasing a crystal grain size of the crystallized amorphous semiconductor film, as a result of an increase in an in-plane temperature of the crystallized amorphous semiconductor film to a second temperature by latent heat released in said crystallizing of the amorphous semiconductor film irradiated with the continuous-wave laser beam, the second temperature ranging from the melting point of the amorphous semiconductor film to a crystalline melting point,
wherein the light intensity distribution continuously convex upward has a width where a light intensity is equal to or higher than a predetermined intensity in a major axis direction, and
the width corresponds to a width of an area included in the amorphous semiconductor film and increased in temperature to the second temperature by the latent heat.

19. A bottom-gate thin-film transistor comprising:
a gate electrode;
an insulating film formed on said gate electrode;
a crystalline semiconductor film formed on said insulating film; and
a source-drain electrode formed on said crystalline semiconductor film,
wherein said crystalline semiconductor film is formed from crystal grains with an average size of 40 nm to 60 nm, and
each of the crystal grains are formed by:
irradiating an amorphous semiconductor film with a continuous-wave laser beam to increase a temperature of the amorphous semiconductor film to a first temperature which is lower than a melting point of the amorphous semiconductor film and at which the amorphous semiconductor film is crystallized by a solid phase growth mechanism, the continuous-wave laser beam having a light intensity distribution which is continuously convex upward on each of major and minor axes;
crystallizing the amorphous semiconductor film irradiated with the continuous-wave laser beam in said irradiating, at the first temperature; and
increasing a crystal grain size of the crystallized amorphous semiconductor film, as a result of an increase in an in-plane temperature of the crystallized amorphous semiconductor film to a second temperature by latent heat released in said crystallizing of the amorphous semiconductor film irradiated with the continuous-wave laser beam, the second temperature ranging from the melting point of the amorphous semiconductor film to a crystalline melting point,
wherein the light intensity distribution continuously convex upward is defined on the major axis to ensure a certain width of an area included in the amorphous semiconductor film and increased to the second temperature by the latent heat.

20. A top-gate thin-film transistor comprising:
a source-drain electrode;
a crystalline semiconductor film formed on said source-drain electrode;
an insulating film formed on said crystalline semiconductor film; and
a gate electrode formed on said insulating film,
wherein said crystalline semiconductor film is formed from crystal grains with an average size of 40 nm to 60 nm, and
each of the crystal grains are formed by:
irradiating an amorphous semiconductor film with a continuous-wave laser beam to increase a temperature of the amorphous semiconductor film to a first temperature which is lower than a melting point of the amorphous semiconductor film and at which the amorphous semiconductor film is crystallized by a solid phase growth mechanism, the continuous-wave laser beam having a light intensity distribution which is continuously convex upward on each of major and minor axes;
crystallizing the amorphous semiconductor film irradiated with the continuous-wave laser beam in said irradiating, at the first temperature; and
increasing a crystal grain size of the crystallized amorphous semiconductor film, as a result of an increase in an in-plane temperature of the crystallized amorphous semiconductor film to a second temperature by latent heat released in said crystallizing of the amorphous semiconductor film irradiated with the continuous-wave laser beam, the second temperature ranging from the melting point of the amorphous semiconductor film to a crystalline melting point,
wherein the light intensity distribution continuously convex upward is defined on the major axis to ensure a certain width of an area included in the amorphous semiconductor film and increased to the second temperature by the latent heat.
